(19) United States
(12) Patent Application Publication
(10) Pub. No.: US 2025/0253258 A1
(43) Pub. Date: Aug. 7, 2025

(54) SEMICONDUCTOR PACKAGE

(71) Applicant: Samsung Electronics Co., Ltd., Suwon-si (KR)

(72) Inventor: Yunseok CHOI, Suwon-si (KR)

(73) Assignee: Samsung Electronics Co., Ltd., Suwon-si (KR)

(21) Appl. No.: 19/026,951

(22) Filed: Jan. 17, 2025

(30) Foreign Application Priority Data
Feb. 5, 2024 (KR) 10-2024-0017620

(51) Int. Cl. H01L 23/538; H01L 23/31; H01L 23/58; H01L 25/18

(52) U.S. Cl. CPC H01L 23/5386; H01L 23/5385; H01L 23/58; H01L 25/18; H01L 23/3107

(57) ABSTRACT

A semiconductor package may include a first package substrate; a power supply device electrically connected to a top surface of the first package substrate; a power management semiconductor chip electrically connected to the top surface of the first package substrate, wherein the power management semiconductor chip is horizontally apart from the power supply device; and a semiconductor device electrically connected to the top surface of the first package substrate, wherein the semiconductor device is horizontally apart from the power management semiconductor chip, wherein the semiconductor device includes: a second package substrate electrically connected to the top surface of the first package substrate; a semiconductor chip electrically connected to a top surface of the second package substrate; and a sub-battery electrically connected to the semiconductor chip through the second package substrate or directly connected to the semiconductor chip.

### CROSS-REFERENCE TO RELATED APPLICATION

This application is based on and claims priority under 35 USC § 119 to Korean Patent Application No. 10-2024-0017620, filed on Feb. 5, 2024, in the Korean Intellectual Property Office, the disclosure of which is incorporated by reference herein in its entirety.

### FIELD

The present disclosure relates to a semiconductor package, and more particularly, to a semiconductor package including a sub-battery and/or power management semiconductor chip.

### BACKGROUND

In available wireless systems and personal systems, maintaining service quality through continuous and stable power supply is very important. Although much progress has been made in battery technology for longer usage period, lifespan, and operating environment, much progress is needed in case of integrating batteries into systems to meet dynamic power needs of the systems. Currently, battery management systems provided for complex electrical and electronic based circuits or devices include rechargeable batteries, such as rechargeable batteries included with laptop computers. Research continues to improve quality of power systems by ensuring that the battery meets the power requirements of systems without interruption, even when systems intermittently require large amounts of power.

### SUMMARY

According to an aspect of the present disclosure, a semiconductor package is provided. The semiconductor package may include a first package substrate; a power supply device electrically connected to a top surface of the first package substrate; a power management semiconductor chip electrically connected to the top surface of the first package substrate, wherein the power management semiconductor chip is horizontally apart from the power supply device, and electrically connected to the power supply device through the first package substrate; and a semiconductor device electrically connected to the top surface of the first package substrate, wherein the semiconductor device is horizontally apart from the power management semiconductor chip, and electrically connected to the power management semiconductor chip through the first package substrate, wherein the semiconductor device includes: a second package substrate electrically connected to the top surface of the first package substrate; a semiconductor chip electrically connected to a top surface of the second package substrate; and a sub-battery electrically connected to the semiconductor chip through the second package substrate or directly connected to the semiconductor chip.

According to another aspect of the present disclosure, a semiconductor package may be provided. The semiconductor package may include a first package substrate; a power supply device electrically connected to a top surface of the first package substrate; a power management semiconductor chip electrically connected to the top surface of the first package substrate, wherein the power management semiconductor chip is horizontally apart from the power supply device, and electrically connected to the power supply device through the first package substrate; a sub-battery electrically connected to the top surface of the first package substrate and configured to be charged by power output from the power management semiconductor chip; and a semiconductor device electrically connected to the top surface of the first package substrate, wherein the semiconductor device comprises a second package substrate and a semiconductor chip electrically connected to a top surface of the second package substrate, wherein the first package substrate is configured to transfer power from the sub-battery to the semiconductor device.

According to another aspect of the present disclosure, a semiconductor package may be provided. The semiconductor package may include a first package substrate; a power supply device electrically connected to a top surface of the first package substrate and configured to charge power; a power management semiconductor chip electrically connected to the top surface of the first package substrate, wherein the power management semiconductor chip is horizontally apart from the power supply device, and electrically connected to the power supply device through the first package substrate; and a semiconductor device electrically connected to the top surface of the first package substrate, wherein the semiconductor device is horizontally apart from the power management semiconductor chip, and electrically connected to the power management semiconductor chip through the first package substrate, wherein the semiconductor device includes: a second package substrate electrically connected to the top surface of the first package substrate; a semiconductor chip electrically connected to a top surface of the second package substrate; a sub-battery configured to supply power to the semiconductor chip; and a molding layer electrically connected to the second package substrate and surrounding the semiconductor chip and the sub-battery, wherein the first package substrate is configured to transfer power from the power management semiconductor chip to the second package substrate of the semiconductor device, and the second package substrate is configured to transfer power received from the first package substrate to the sub-battery.

### BRIEF DESCRIPTION OF THE DRAWINGS

Embodiments will be more clearly understood from the following detailed description taken in conjunction with the accompanying drawings in which:

FIG. 1 is a plan view schematically illustrating a semiconductor package according to an embodiment;

FIG. 2 is a cross-sectional view schematically illustrating the semiconductor package of FIG. 1 taken along line A-A′ of FIG. 1;

FIG. 3 is a cross-sectional view schematically illustrating a semiconductor package taken along line A-A′ of FIG. 1 according to an embodiment;

FIG. 4 is a cross-sectional view schematically illustrating a semiconductor package taken along line A-A′ of FIG. 1 according to an embodiment;

FIG. 5 is a cross-sectional view schematically illustrating a semiconductor package taken along line A-A′ of FIG. 1 according to an embodiment;

FIG. 6 is a plan view schematically illustrating a semiconductor package according to an embodiment;

FIG. 7 is a plan view schematically illustrating a semiconductor package according to an embodiment;

FIG. 8 is a cross-sectional view schematically illustrating the semiconductor package of FIG. 7 taken along line B-B′ of FIG. 7;

FIG. 9 is a plan view schematically illustrating a semiconductor package according to an embodiment; and

FIG. 10 is a plan view schematically illustrating a semiconductor package according to an embodiment.

### DETAILED DESCRIPTION OF THE EMBODIMENTS

The embodiments may be modified in various ways and take on various alternative forms, and specific embodiments thereof are shown in the drawings and described in detail below. However, this is not intended to limit the present embodiments to the specific disclosure form.

The present disclosure provides a semiconductor package capable of continuously supplying power to a semiconductor device and improve the power stability of said semiconductor device.

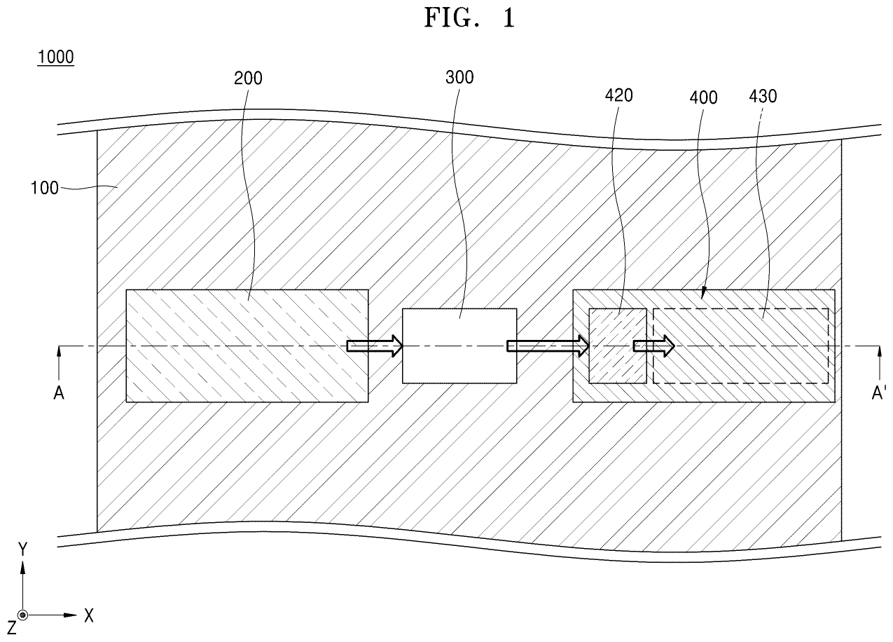

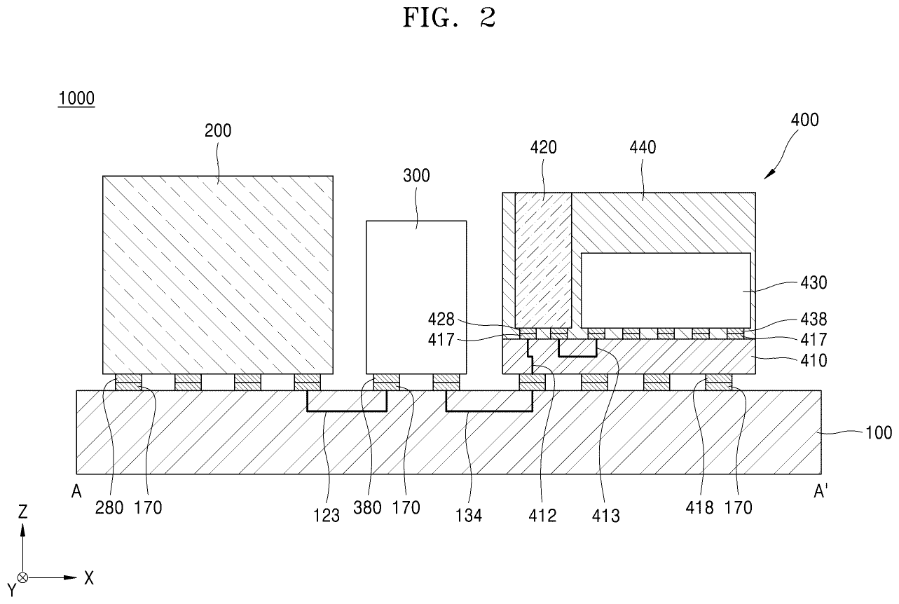

FIG. 1 is a plan view schematically illustrating a semiconductor package 1000 according to an embodiment. FIG. 2 is a cross-sectional view schematically illustrating the semiconductor package 1000 of FIG. 1 taken along line A-A′ of FIG. 1.

Referring to FIGS. 1 and 2, the semiconductor package 1000 may include a first package substrate 100, a power supply device 200, a power management semiconductor chip 300, and a semiconductor device 400. The semiconductor device 400 may include a second package substrate 410, a sub-battery 420, and a semiconductor chip 430.

Hereinafter, unless otherwise defined, a direction parallel to an upper surface of the first package substrate 100 is defined as a first horizontal direction (an X direction), a direction perpendicular to the upper surface of the first package substrate 100 is a vertical direction (a Z direction), and a direction perpendicular to the first horizontal direction (the X direction) and the vertical direction (the Z direction) is defined as a second horizontal direction (a Y direction). A direction of combining the first horizontal direction (the X direction) and the second horizontal direction (the Y direction) is defined as a horizontal direction.

The first package substrate 100 may be, for example, a printed circuit board (PCB). The first package substrate 100 may include a core insulating layer including at least one material selected from phenol resin, epoxy resin, and polyimide.

For example, the core insulating layer may include at least one selected from polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

However, the present disclosure is not limited thereto, and in some embodiments, the first package substrate 100 may be an interposer including a substrate and a through-substrate-via penetrating the substrate. For example, the first package substrate 100 may be a glass interposer or a silicon interposer. In some embodiments, the first package substrate 100 may be a redistribution structure that includes a redistribution pattern and a redistribution insulating layer surrounding the redistribution pattern.

The first package substrate 100 may include a plurality of upper pads, e.g., upper pad 170, located on an upper surface of a core insulating layer. The upper pads may be part of a circuit interconnection patterned on the upper surface of the core insulating layer. For example, the first package substrate 100 may electrically connect components that are electrically connected to the upper pads. For example, the first package substrate 100 may include an internal interconnection that electrically connects the upper pads to one another.

In some embodiments, the first package substrate 100 may include a plurality of package substrate lower pads located on a lower surface of the core insulating layer. External connection terminals may be attached to the package substrate lower pads and may electrically and physically connect the first package substrate 100 to an external device on which the first package substrate 100 is mounted. For example, the external connection terminals may be formed, for example, from solder balls or solder bumps.

In some embodiments, the upper pad 170 and the package substrate lower pad may each include copper, nickel, stainless steel, or beryllium copper. An internal interconnection may be formed within the first package substrate 100 to electrically connect the upper pad 170 to the package substrate lower pad.

The power supply device 200 may be located on the first package substrate 100. The power supply device 200 may supply power to the semiconductor device 400. For example, an output voltage of the power supply device 200 may be greater than a rated voltage of the semiconductor device 400.

In some embodiments, the power supply device 200 may be configured to charge power. For example, the power supply device 200 may be a storage battery configured to charge power. For example, the power supply device 200 may include a lead (Pb) storage battery, a nickel-cadmium (Ni—Cd) battery, a nickel-hydrogen (Ni-MH) battery, a lithium ion battery, and/or a lithium polymer battery.

The power supply device 200 may be electrically connected to the first package substrate 100 through the lower pad 280 located on a lower surface of the power supply device 200. For example, the lower pad 280 of the power supply device 200 may be electrically connected to the upper pad 170 of the first package substrate 100 through a connection terminal. However, the present disclosure is not limited thereto, and the lower pad 280 of the power supply device 200 may be electrically connected to the upper pad 170 of the first package substrate 100 using known methods and processes, e.g., an adhesive film, such as an anisotropic conductive film (ACF), a non-conductive film (NCF), etc.

The power management semiconductor chip 300 may include an active surface and an inactive surface opposite to the active surface. The power management semiconductor chip 300 may be located on the first package substrate 100. The power management semiconductor chip 300 may be apart from the power supply device 200 in a horizontal direction.

A semiconductor device layer including individual devices may be provided on the active surface of the power management semiconductor chip 300. The individual devices may include, e.g., transistors. In embodiments, the power management semiconductor chip 300 may include a power management integrated circuit (PMIC).

The power management semiconductor chip 300 may be configured to receive power from the power supply device 200 and convert the received power into rated power of the semiconductor device 400. For example, when the semiconductor package 1000 includes a plurality of semiconductor devices 400, the power management semiconductor chip 300 may adjust power supplied from the power supply device 200 to suit to rated power and supply the adjusted power to each of the semiconductor devices 400.

The power management semiconductor chip 300 may be electrically connected to the first package substrate 100. For example, the power management semiconductor chip 300 may be connected to the first package substrate 100 in a manner such that the active surface of the power management semiconductor chip 300 faces the first package substrate 100, e.g., in a face-down manner. For example, the lower pad 380 of the power management semiconductor chip 300 may be electrically connected to the upper pad 170 of the first package substrate 100 through a connection terminal. However, a method of electrically connecting the power management semiconductor chip 300 to the first package substrate 100 is not limited thereto.

The semiconductor device 400 may include the second package substrate 410, the semiconductor chip 430, and the sub-battery 420. The semiconductor device 400 may be located on the first package substrate 100. The semiconductor device 400 may be apart from the power supply device 200 and the power management semiconductor chip 300 in the horizontal direction. The power management semiconductor chip 300 may be located between the semiconductor device 400 and the power supply device 200. The semiconductor device 400 may receive power from the power management semiconductor chip 300.

The second package substrate 410 may be a PCB. In addition, the second package substrate 410 may be an interposer or a redistribution structure. The second package substrate 410 may be located on the first package substrate 100.

In some embodiments, the second package substrate 410 may be larger than the semiconductor chip 430. The second package substrate 410 may extend an input/output pad 438 of the semiconductor chip 430 externally.

The second package substrate 410 may include an upper pad 417 located on an upper surface of the second package substrate 410 and a lower pad 418 located on a lower surface of the second package substrate 410. In some embodiments, the pitch and size of the upper pad 417 may be smaller than the pitch and size of the lower pad 418.

The second package substrate 410 may be electrically connected to the first package substrate 100. The lower pad 418 of the second package substrate 410 may be electrically connected to the upper pad 170 of the first package substrate 100.

In some embodiments, the first package substrate 100 may include a first internal interconnection 123 that transfers power from the power supply device 200 to the power management semiconductor chip 300 and a second internal interconnection 134 that transfers power from the power management semiconductor chip 300 to the second package substrate 410.

In some embodiments, the first internal interconnection 123 may extend from the upper pad 170 of the first package substrate 100 electrically connected to a power pad, which is one of the lower pads (e.g., lower pad 280) of the power supply device 200, to the upper pad 170 of the first package substrate 100 electrically connected to a power pad, which is one of the lower pads (e.g., lower pad 380) of the power management semiconductor chip 300.

In some embodiments, the second internal interconnection 134 may extend from the upper pad 170 of the first package substrate 100 electrically connected to a power pad, which is one of the lower pads (e.g., lower pad 380) of the power supply device 200, to the upper pad 170 of the first package substrate 100 electrically connected to a power pad, which is one of the lower pads (e.g., lower pad 418) of the second package substrate 410.

For example, the power supplied to the second package substrate 410 may be power output from the power management semiconductor chip 300. That is, the power output from the power supply device 200 may pass through the power management semiconductor chip 300 through the first internal interconnection 123 and then be input to the semiconductor device 400 through the second internal interconnection 134.

The semiconductor chip 430 may include an active surface and an inactive surface opposite to the active surface. The semiconductor chip 430 may be located on an upper surface of the second package substrate 410. The semiconductor chip 430 may be electrically connected to the second package substrate 410.

In some embodiments, the semiconductor chip 430 may be connected to the second package substrate 410 with the active surface of the semiconductor chip 430 facing the second package substrate 410. That is, the semiconductor chip 430 may be disposed on the second package substrate 410 in a face-down manner.

For example, the semiconductor chip 430 may be mounted on the second package substrate 410 in a face-down manner so that the input/output pads (e.g., input/output pad 438) face the second package substrate 410. For example, the semiconductor chip 430 may be mounted on the second package substrate 410 in a flip-chip (FC) manner.

In some embodiments, the input/output pad 438 of the semiconductor chip 430 may be electrically connected to the upper pad 417 of the second package substrate 410 through a connection terminal. However, without being limited thereto, the semiconductor chip 430 may be electrically connected to the second package substrate 410 through any suitable method of process, e.g., by using adhesive films, such as an ACF and an NCF.

The semiconductor chip 430 may include, for example, silicon (Si). Alternatively, the semiconductor chip 430 may include a semiconductor element, such as germanium (Ge), or a compound semiconductor, such as silicon carbide (SiC), gallium arsenide (GaAs), indium arsenide (InAs), and indium phosphide (InP).

The semiconductor chip 430 may include a conductive region, for example, a well doped with impurities, or a structure doped with impurities. A semiconductor device layer including individual devices may be provided on the active surface of the semiconductor chip 430. The individual devices may include, for example, transistors. The individual devices may include microelectronic devices, for example, image sensors, such as metal-oxide-semiconductor field effect transistor (MOSFET), system large scale integration (LSI), complementary metal-oxide-semiconductor (CMOS) imaging sensor (CIS), etc., and micro-electro-mechanical system (MEMS), active devices, passive devices, etc.

The semiconductor chip 430 may be a memory chip or a logic chip. The memory chip may include a volatile memory semiconductor device, such as dynamic random access memory (DRAM) and static random access memory (SRAM), or nonvolatile memory semiconductor device, such as phase-change random access memory (PRAM), magnetoresistive random access memory (MRAM), ferroelectric random access memory (FeRAM), resistive random access memory (RRAM). The logic chip may include a central processing unit (CPU) chip, a graphics processing unit (GPU) chip, an application processor (AP) chip, or an application specific integrated circuit (ASIC) chip.

In FIG. 2, one semiconductor chip 430 is shown to be mounted on the second package substrate 410, but the number of semiconductor chips 430 is not limited thereto, and two or more semiconductor chips, similar to or different than semiconductor chip 430, may be mounted thereon. When two or more semiconductor chips are mounted on the second package substrate 410, the semiconductor chips may be of same or different types. For example, when two or more semiconductor chips are mounted on the second package substrate 410, the semiconductor chips may be stacked in a vertical direction (the Z direction) and directly connected to each other or may be apart in the horizontal direction and electrically connected to each other through the second package substrate 410.

The sub-battery 420 may be located on the second package substrate 410. The sub-battery 420 may be apart from the semiconductor chip 430 in the horizontal direction. The sub-battery 420 may be electrically connected to the second package substrate 410 and configured to be charged with power supplied to the second package substrate 410. For example, the sub-battery 420 may be a lead (Pb) storage battery, a nickel-cadmium (Ni—Cd) battery, a nickel-hydrogen (Ni-MH) battery, a lithium ion battery, and/or a lithium polymer battery.

In some embodiments, the sub-battery 420 may be smaller in size than the power supply device 200. For example, the volume of the sub-battery 420 may be less than the volume of the power supply device 200. In some embodiments, when the power supply device 200 is a capacitor, charging capacity of the sub-battery 420 may be less than charging capacity of the power supply device 200. However, the charging capacity of the sub-battery 420 relative to the volume may be greater than the charging capacity of the power supply device 200 relative to the volume. In this specification, “charge capacity relative to volume” refers to a value obtained by dividing charge capacity by volume.

The sub-battery 420 may include a plurality of lower pads (e.g., lower pad 428) located on the lower surface of the sub-battery 420. The lower pad 428 of the sub-battery 420 may be electrically connected to the upper pad 417 of the second package substrate 410 through a connection terminal.

The sub-battery 420 may supply power to the semiconductor chip 430 through the second package substrate 410. The second package substrate 410 may include a third internal interconnection 412 that electrically connects the first package substrate 100 to the sub-battery 420 and a fourth internal interconnection 413 that electrically connects the sub-battery 420 to the semiconductor chip 430.

In some embodiments, the third internal interconnection 412 may electrically connect the upper pad 417 of the second package substrate 410 to the lower pad 418 of the second package substrate 410. For example, the third internal interconnection 412 may extend from the lower pad 418 of the second package substrate 410 to the upper pad 417 of the second package substrate 410 electrically connected to a power pad, which is one of the lower pads (e.g., lower pad 428) of the sub-battery 420.

In some embodiments, the fourth internal interconnection 413 may electrically connect the lower pad 428 of the sub-battery 420 to the input/output pad 438 of the semiconductor chip 430. For example, the fourth internal interconnection 413 may extend from the upper pad 417 of the second package substrate 410 electrically connected to a power pad, which is one of the lower pads (e.g., lower pad 428) of the sub-battery 420, to the upper pad 417 of the second package substrate 410 electrically connected to a power pad, which is one of the input/output pads (e.g., input/output pad 438) of the semiconductor chip 430.

Power supplied from the first package substrate 100 to the second package substrate 410 may be transferred to the sub-battery 420 through the third internal interconnection 412. The sub-battery 420 may be charged by power supplied from the power management semiconductor chip 300 to the second package substrate 410.

The sub-battery 420 may transfer the charged power to the semiconductor chip 430 through the fourth internal interconnection 413. For example, power provided from the power management semiconductor chip 300 to the semiconductor chip 430 may pass through the sub-battery 420 and then be supplied to the semiconductor chip 430.

Power stability of the semiconductor chip 430 may be improved by continuously supplying power to the semiconductor chip 430 through the sub-battery 420. For example, regardless of the stability of power discharged by the power supply device 200, power is provided to the semiconductor chip 430 through power charged by the sub-battery 420, thereby maintaining the power stability of the semiconductor chip 430. In addition, when the semiconductor chip 430 momentarily requires a large amount of power, additional power may be provided to the semiconductor chip 430 through the sub-battery 420. In such a manner, the semiconductor package 1000 may provide power in accordance with the power requirement of the semiconductor chip 430. Accordingly, the performance of the semiconductor chip 430 may be improved.

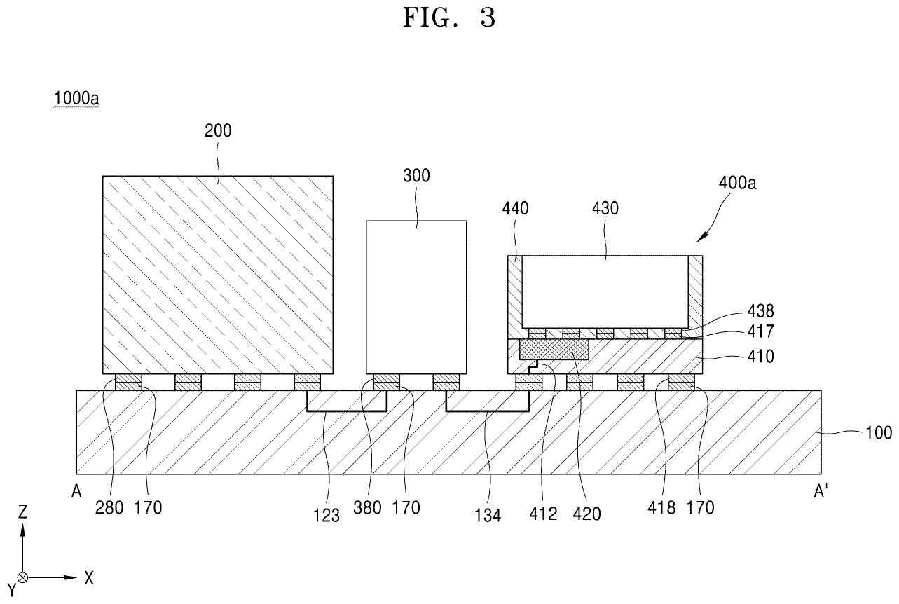

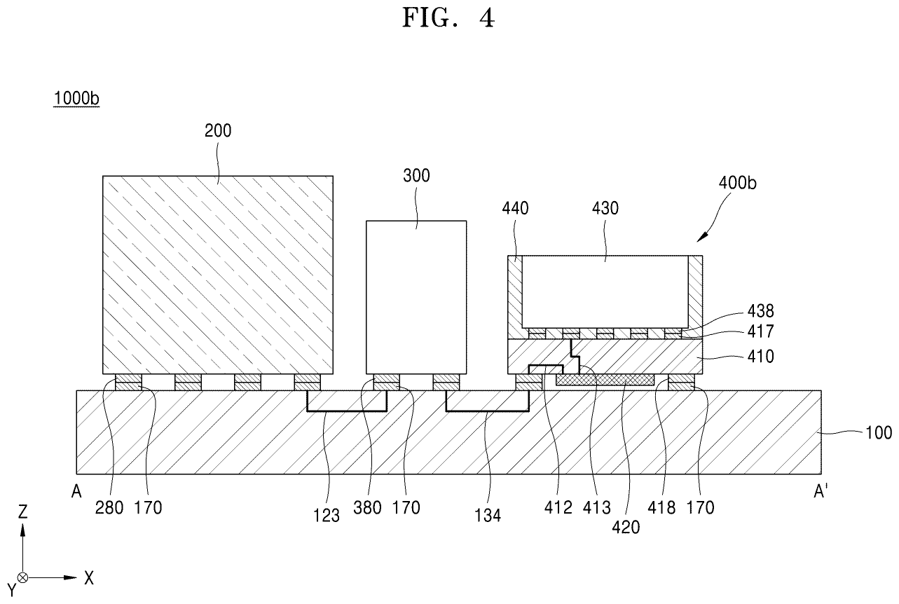

For example, in FIG. 2, the sub-battery 420 is shown as being located on the second package substrate 410, but the location of the sub-battery 420 is not limited thereto. Referring to FIGS. 3 and 4, the location of the sub-battery 420 is described.

FIG. 3 is a cross-sectional view schematically illustrating a semiconductor package 1000a taken along line A-A′ of FIG. 1 according to an embodiment.

In semiconductor package 1000a of FIG. 3, the sub-battery 420 of a semiconductor device 400a may be located inside the second package substrate 410. For example, the second package substrate 410 may have a cavity recessed from the upper surface of the second package substrate 410 inwardly. The sub-battery 420 may be located within the cavity of the second package substrate 410 and electrically connected to the semiconductor chip 430. In some embodiments, the sub-battery 420 may be surrounded on at least two sides by the second package substrate 410 and an upper surface of the sub-battery 420 may be on a same level as an upper surface of the second package substrate 410. In some embodiments, the sub-battery 420 may overlap the semiconductor chip 430 in the vertical direction (the Z direction).

FIG. 4 is a cross-sectional view schematically illustrating a semiconductor package 1000b taken along line A-A′ of FIG. 1 according to an embodiment.

In semiconductor package 1000b of FIG. 4, the sub-battery 420 of a semiconductor device 400b may be located on the lower surface of the second package substrate 410 or under the second package substrate in the vertical direction (the Z direction). The sub-battery 420 may be apart from the semiconductor chip 430 in the vertical direction (the Z direction) and may be separated by a width of the second package substrate 410. For example, the sub-battery 420 may be located on the lower surface of the second package substrate 410, and the semiconductor chip 430 may be located on the upper surface of the second package substrate 410.

By locating the sub-battery 420 below, under, or inside the second package substrate 410, the size of the second package substrate 410 may be reduced relatively.

Referring back to FIG. 2, the semiconductor device 400 may further include a molding layer 440. The molding layer 440 may be located on the second package substrate 410 and may include the sub-battery 420 and the semiconductor chip 430. In embodiments, the molding layer 440 may not include the sub-battery 420.

In some embodiments, an upper surface of the molding layer 440 may be coplanar with the upper surface of the sub-battery 420 and/or the semiconductor chip 430. For example, in the process of forming the molding layer 440, in a state in which the molding layer 440 is formed to cover the upper surfaces of the sub-battery 420 and the semiconductor chip 430, an upper portion of the molding layer 440 may be removed so that the upper surface of one of the sub-battery 420 and the semiconductor chip 430 is exposed externally. Accordingly, the upper surface of the molding layer 440 may be coplanar with the upper surface of one of the sub-battery 420 or the semiconductor chip 430 having a higher vertical level. For example, if the vertical level of the upper surface of the sub-battery 420 is higher than the vertical level of the upper surface of the semiconductor chip 430, the upper surface of the sub-battery 420 may be coplanar with the upper surface of the molding layer 440.

In some embodiments, an outer surface of the molding layer 440 may be coplanar with an outer surface of the second package substrate 410. For example, a side surface of the molding layer 440 may be a side surface of the semiconductor device 400. The molding layer 440 may protect the semiconductor chip 430 and the sub-battery 420 from the outside.

In some embodiments, the molding layer 440 may include epoxy resin or polyimide resin. The molding layer 440 may include, for example, epoxy molding compound (EMC).

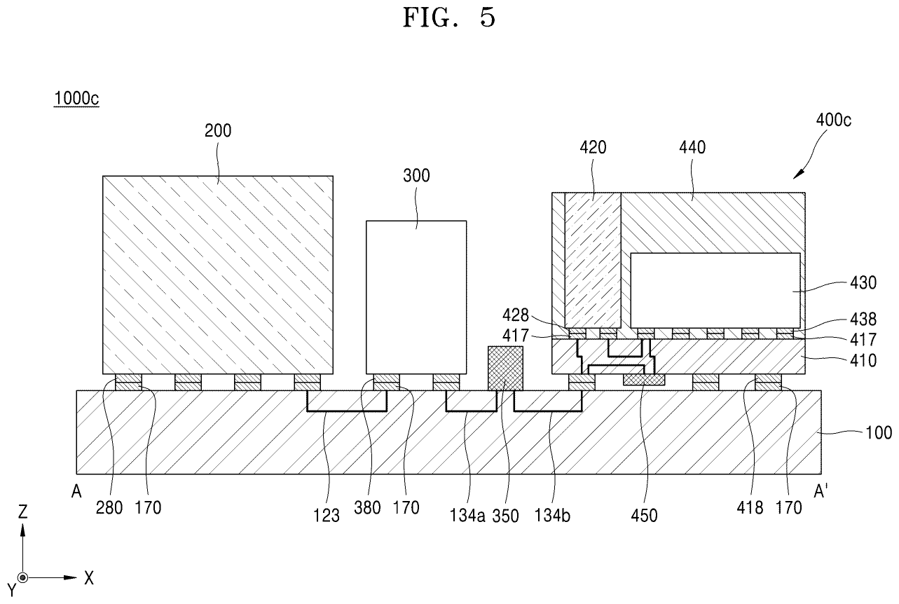

FIG. 5 is a cross-sectional view schematically illustrating a semiconductor package 1000c taken along line A-A′ of FIG. 1 according to an embodiment.

Most of the components constituting the semiconductor package 1000c described below and the materials making up the components thereof are substantially the same as or similar to those described above with reference to FIG. 2. Therefore, for convenience of description, the differences between the semiconductor package 1000c of FIG. 5 and the semiconductor package 1000 of FIG. 2 are mainly described.

Referring to FIG. 5, the semiconductor package 1000c may include the first package substrate 100, the power supply device 200, the power management semiconductor chip 300, and a semiconductor device 400c. The semiconductor package 1000c may include a first passive device 350 and a second passive device 450.

The first passive device 350 may be located on the first package substrate 100. For example, the first passive device 350 may be located near the power management semiconductor chip 300 or may be electronically connected to the first package substrate between the power management semiconductor chip 300 and semiconductor device 400c. The first passive device 350 may adjust an output voltage of the power management semiconductor chip 300 or remove noise.

For example, the first passive device 350 may include at least one of a resistor, an inductor, and a capacitor. For example, the first passive device 350 may be a multilayer ceramic capacitor (MLCC) or a silicon capacitor.

In some embodiments, power output from the power management semiconductor chip 300 may be supplied to the second package substrate 410 through the first passive device 350. For example, the first package substrate 100 may include a fifth internal interconnection 134a electrically connecting the power management semiconductor chip 300 to the first passive device 350 and a sixth internal interconnection 134b electrically connecting the first passive device 350 to the second package substrate 410. That is, power supplied from the power management semiconductor chip 300 to the semiconductor device 400c may pass through the first passive device 350 before being input to the semiconductor device 400c.

The semiconductor device 400c may include the second passive device 450. The second passive device 450 may be located on an upper or lower surface of the second package substrate 410. In addition, the second passive device 450 may be located inside the second package substrate 410.

The second passive device 450 may remove noise from power provided to the semiconductor chip 430. For example, the second passive device 450 may be an MLCC or a silicon capacitor.

In some embodiments, the second passive device 450 may be connected in parallel with the sub-battery 420. For example, in the process of transferring power from the second package substrate 410 to the semiconductor chip 430, the second passive device 450 may be connected in parallel with the sub-battery 420.

Through the first passive device 350 and the second passive device 450, noise occurring in the process of transferring power from the power supply device 200 to the semiconductor chip 430 may be suppressed or the output voltage may be appropriately adjusted.

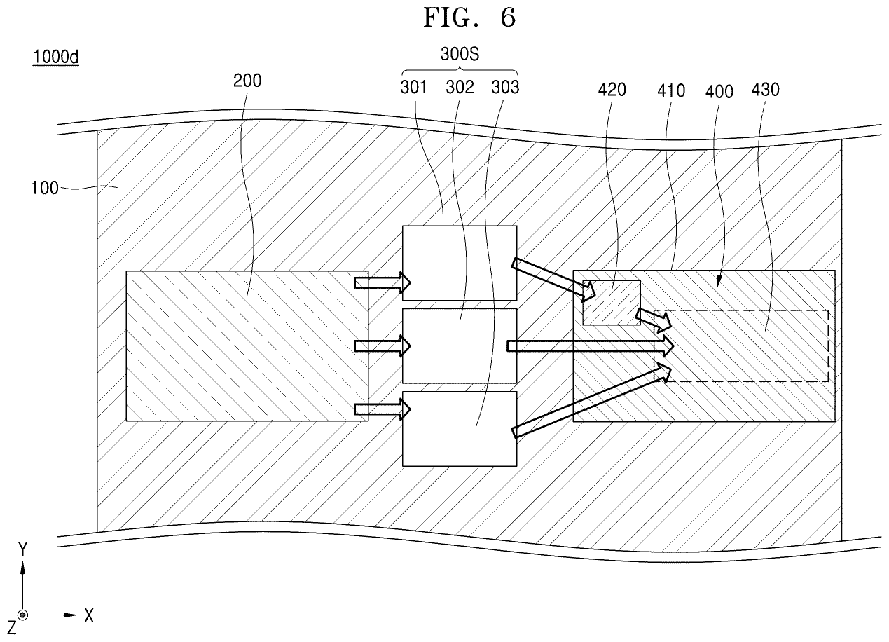

FIG. 6 is a plan view schematically illustrating a semiconductor package 1000d according to an embodiment.

Most of the components constituting the semiconductor package 1000d described below and the materials making up the components thereof are substantially the same as or similar to those described above with reference to FIG. 1. Therefore, for convenience of description, the differences between the semiconductor package 1000d of FIG. 6 and the semiconductor package 1000 of FIG. 1 are mainly described.

Referring to FIG. 6, the semiconductor package 1000d may include the first package substrate 100, the power supply device 200, a plurality of power management semiconductor chips 300S, and the semiconductor device 400.

The power management semiconductor chips 300S may receive power from the power supply device 200 and output power to the semiconductor device 400. Output voltages of the power management semiconductor chips 300S may be different from each other. In embodiments, output voltages of some of the power management semiconductor chips 300S is the same.

The rated voltage of the semiconductor chip 430 may vary depending on the usage situation. That is, the semiconductor chip 430 may have a plurality of rated voltages. The output voltage of each of the power management semiconductor chips 300S may be equal to one of the rated voltages of the semiconductor chip 430. Accordingly, depending on the usage situation of the semiconductor chip 430, the power management semiconductor chip having an output voltage equal to the rated voltage of the semiconductor chip 430 among the power management semiconductor chips 300S may be electrically connected to the semiconductor chip 430.

In some embodiments, one of the power management semiconductor chips 300S may supply power to the sub-battery 420, and one or more of the others of the power management semiconductor chips 300S may supply power to the semiconductor chip 430. For example, the output voltage of one of the power management semiconductor chips 300S may be equal to the rated voltage of the sub-battery 420, and each of the output voltages of the others of the power management semiconductor chips 300S may be equal to one of a plurality of rated voltages of the semiconductor chip 430.

In some embodiments, the power management semiconductor chips 300S may include a first power management semiconductor chip 301, a second power management semiconductor chip 302, and a third power management semiconductor chip 303. In FIG. 6, an embodiment in which three power management semiconductor chips 300S are included is shown, but the number and location of the power management semiconductor chips 300S are not limited thereto.

The first power management semiconductor chip 301, the second power management semiconductor chip 302, and the third power management semiconductor chip 303 may receive power from the same power supply device 200 or may receive power from different power supply devices.

The output voltages of the first power management semiconductor chip 301, the second power management semiconductor chip 302, and the third power management semiconductor chip 303 may be different from each other. For example, the output voltage of the first power management semiconductor chip 301 may be greater than the output voltage of the second power management semiconductor chip 302. The output voltage of the second power management semiconductor chip 302 may be greater than the output voltage of the third power management semiconductor chip 303. The semiconductor chip 430 may receive power from at least one of the first power management semiconductor chip 301, the second power management semiconductor chip 302, and the third power management semiconductor chip 303 depending on the situation.

The first power management semiconductor chip 301, the second power management semiconductor chip 302, and the third power management semiconductor chip 303 may supply power to the second package substrate 410. The second package substrate 410 may include an internal interconnection to transfer power input from the first power management semiconductor chip 301 to the sub-battery 420. That is, the power output from the first power management semiconductor chip 301 may be charged to the sub-battery 420. The output voltage of the first power management semiconductor chip 301 may be equal to the rated voltage of the sub-battery 420.

The second package substrate 410 may be configured to transfer power input from each of the second power management semiconductor chip 302 and the third power management semiconductor chip 303 to the semiconductor chip 430. That is, the second package substrate 410 may include an internal interconnection to transfer power input from each of the second power management semiconductor chip 302 and the third power management semiconductor chip 303 to the semiconductor chip 430. That is, power input from the second power management semiconductor chip 302 and the third power management semiconductor chip 303 to the second package substrate 410 may be transferred to the semiconductor chip 430 without passing through the sub-battery 420.

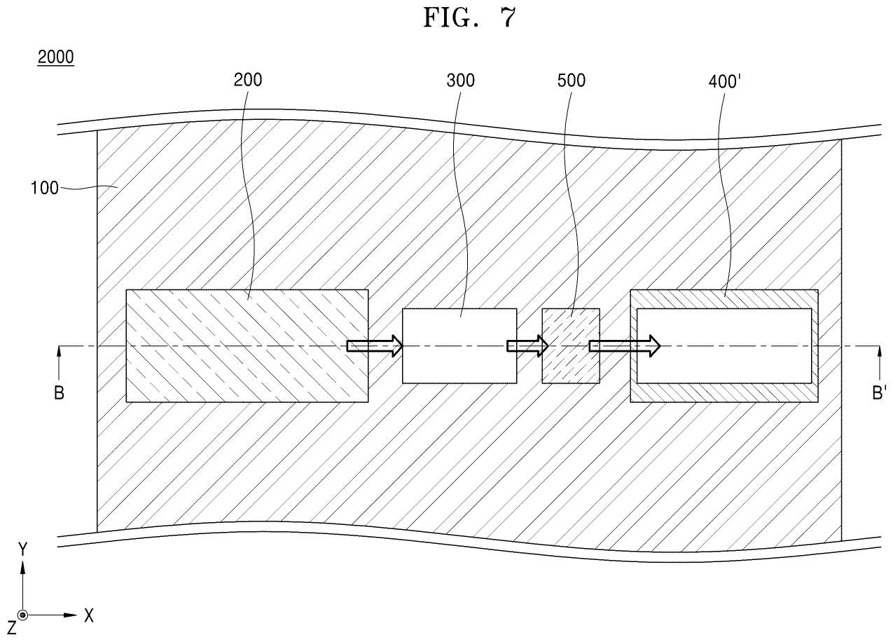

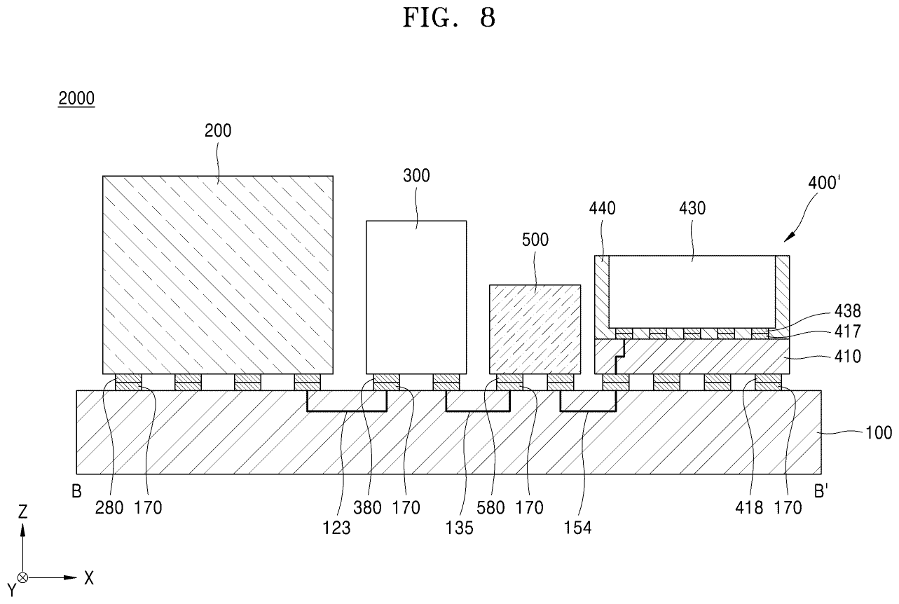

FIG. 7 is a plan view schematically illustrating a semiconductor package 2000 according to an embodiment. FIG. 8 is a cross-sectional view schematically illustrating the semiconductor package 2000 of FIG. 7 taken along line B-B′ of FIG. 7.

Most of the components constituting the semiconductor package 2000 described below and the materials making up the components thereof are substantially the same as or similar to those described above with reference to FIG. 1. Therefore, for convenience of description, the differences between the semiconductor package 2000 of FIG. 7 and the semiconductor package 1000 of FIG. 1 are mainly described.

The semiconductor package 2000 may include the first package substrate 100, the power supply device 200, the power management semiconductor chip 300, a sub-battery 500, and a semiconductor device 400′.

The first package substrate 100 may have a flat shape. The first package substrate 100 may be a PCB, an interposer, or a redistribution structure. The power supply device 200 and the power management semiconductor chip 300 may be located on the first package substrate 100. The first package substrate 100 may include a first internal interconnection 123 that electrically connects the upper pad 170 of the first package substrate 100 to which the power supply device 200 is connected to the upper pad of the first package substrate 100 to which the power management semiconductor chip 300 is connected.

The power supply device 200 may supply power to the power management semiconductor chip 300 through the first internal interconnection 123, and the power management semiconductor chip 300 may lower power supplied from the power supply device 200 to rated power of the sub-battery 500 and output the lowered power. In some embodiments, power provided by the power supply device 200 may pass through the power management semiconductor chip 300 and be transferred to the semiconductor device 400′.

The sub-battery 500 may be located on the first package substrate 100. For example, a lower pad 580 of the sub-battery 500 may be electrically connected to the upper pad 170 of the first package substrate 100. For example, the sub-battery 500 may be attached to the first package substrate 100 through a connection terminal, such as a solder ball. The sub-battery 500 may be substantially the same as the sub-battery 420 (see FIG. 2) described above.

In some embodiments, a distance between the sub-battery 500 and the semiconductor device 400′ may be less than a distance between the power management semiconductor chip 300 and the semiconductor device 400′. For example, the sub-battery 500 may be located or electronically connected to a upper surface or top surface of the first package substrate 100 between the power management semiconductor chip 300 and the semiconductor device 400′. For example, by reducing a power transmission distance between the sub-battery 500 and the semiconductor device 400′ and reducing a power transmission distance between the power management semiconductor chip 300 and the sub-battery 500, the occurrence of noise may be suppressed.

The sub-battery 500 may receive power from the power management semiconductor chip 300. For example, the sub-battery 500 may be charged through power input to the power management semiconductor chip 300. For example, the rated voltage and output voltage of the sub-battery 500 may be substantially the same. The output voltage of the sub-battery 500 may be substantially the same as the rated voltage of the semiconductor chip 430.

In some embodiments, the first package substrate 100 may be configured to transfer power output from the power management semiconductor chip 300 to the sub-battery 500. For example, the first package substrate 100 may include a seventh internal interconnection 135 that electrically connects the upper pad 170 of the first package substrate 100 connected to the power management semiconductor chip 300 to the upper pad of the first package substrate 100 connected to the sub-battery 500.

In some embodiments, the first package substrate 100 may be configured to transfer power output from the sub-battery 500 to the second package substrate 410 of the semiconductor device 400′. The first package substrate 100 may include an eighth internal interconnection 154 that electrically connects the upper pad 170 of the first package substrate 100 connected to the sub-battery 500 to the upper pad 170 of the first package substrate 100 connected to the semiconductor device 400′.

For example, power output from the power management semiconductor chip 300 may be charged in the sub-battery 500 and then transferred to the semiconductor chip 430 of the semiconductor device 400′. By charging the sub-battery 500 with power supplied to the semiconductor chip 430, the semiconductor package 2000 may stably supply power to the semiconductor chip 430.

The semiconductor device 400′ may include a second package substrate 410, a semiconductor chip 430, and a molding layer 440. The second package substrate 410 may be located on the first package substrate 100, and the semiconductor chip 430 may be located on the second package substrate 410. The molding layer 440 may be located on the second package substrate 410 and may surround the semiconductor chip 430. The second package substrate 410, the semiconductor chip 430, and the molding layer 440 may be substantially, and respectively, the same as the second package substrate 410, the semiconductor chip 430, and the molding layer 440 of FIG. 2 described above.

In some embodiments, the semiconductor device 400′ may receive power from the sub-battery 500. For example, the first package substrate 100 may be configured to transfer power output from the sub-battery 500 to the semiconductor device 400′. For example, all power supplied to the first package substrate 100 may be the power charged in the sub-battery 500.

In some embodiments, the second package substrate 410 may extend the input/output pad 438 of the semiconductor chip 430 externally. For example, a portion of the lower pad 418 of the second package substrate 410 may overlap the semiconductor chip 430 in the vertical direction (the Z direction), and another portion thereof may not overlap the semiconductor chip 430 in the vertical direction (the Z direction). In some embodiments, an upper surface of the semiconductor chip 430 may be coplanar with an upper surface of the molding layer 440.

In some embodiments, the semiconductor package 2000 may include the first passive device 350 (see FIG. 5) and the second passive device 450 (see FIG. 5). The first passive device 350 may help control the output voltage of the power management semiconductor chip 300 and suppress noise, and the second passive device 450 may help suppress noise in the power supplied to the semiconductor chip 430.

In some embodiments, the first passive device 350 may be located on the first package substrate 100. The second passive device 450 may be located on the first package substrate 100 or on the second package substrate 410. That is, the second passive device 450 may be adjacent to the sub-battery 500 or adjacent to the semiconductor chip 430.

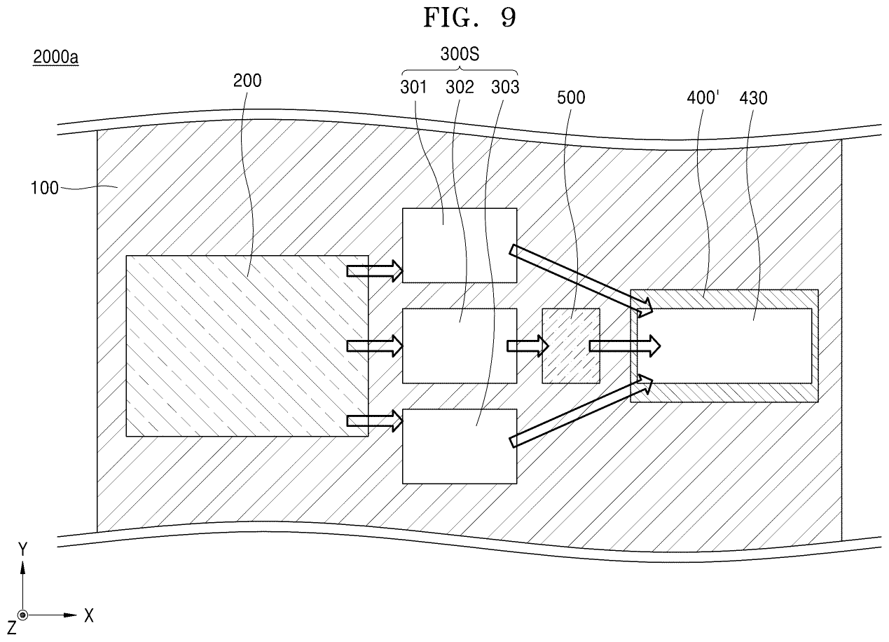

FIG. 9 is a plan view schematically illustrating a semiconductor package 2000a according to an embodiment.

Most of the components constituting the semiconductor package 2000a described below and the materials making up the components thereof are substantially the same as or similar to those described above with reference to FIG. 7. Therefore, for convenience of description, the differences between the semiconductor package 2000a of FIG. 9 and the semiconductor package 2000 of FIG. 7 are mainly described.

The semiconductor package 2000a may include the first package substrate 100, the power supply device 200, the plurality of power management semiconductor chips 300S, the sub-battery 500, and the semiconductor device 400′.

The power management semiconductor chips 300S may receive power from the power supply device 200 and output power to the semiconductor device 400′. Voltages of power output from the power management semiconductor chips 300S may be different.

The voltage of power required by the semiconductor chip 430 may vary depending on the situation. That is, the semiconductor chip 430 may have a plurality of voltages for required power. The voltage of the output power of each of the power management semiconductor chips 300S may be equal to one of the voltages of the required power of the semiconductor chip 430. Accordingly, depending on the situation, the semiconductor chip 430 may be electrically connected to a power management semiconductor chip that outputs power having a voltage which is the same as that of the required power of the semiconductor chip 430 among the power management semiconductor chips 300S.

In some embodiments, one of the power management semiconductor chips 300S supplies power to the sub-battery 500, and the others of the power management semiconductor chips 300S may supply power directly to the semiconductor device 400′. For example, the output voltage of one of the power management semiconductor chips 300S may be equal to the rated voltage of the sub-battery 500, and the output voltages of the others of the power management semiconductor chips 300S may be equal to a plurality of rated voltages of the semiconductor chip 430.

For example, the first package substrate 100 may include an internal interconnection to supply power from one of the power management semiconductor chips 300S to the sub-battery 500 and include an internal interconnection to supply power from the others of the power management semiconductor chips 300S to the semiconductor device 400′.

In some embodiments, the power management semiconductor chips 300S may include the first power management semiconductor chip 301, the second power management semiconductor chip 302, and the third power management semiconductor chip 303.

Output voltages of the first power management semiconductor chip 301, the second power management semiconductor chip 302, and the third power management semiconductor chip 303 may be different from each other. For example, each of the output voltages of the first power management semiconductor chip 301, the second power management semiconductor chip 302, and the third power management semiconductor chip 303 may be equal to one of the rated voltages of the semiconductor chip 430.

In some embodiments, the first power management semiconductor chip 301 and the third power management semiconductor chip 303 may provide power directly to the semiconductor device 400′, and the second power management semiconductor chip 302 may provide power to the sub-battery 500. That is, the second power management semiconductor chip 302 may charge the sub-battery 500, and the sub-battery 500 may provide power to the semiconductor chip 430.

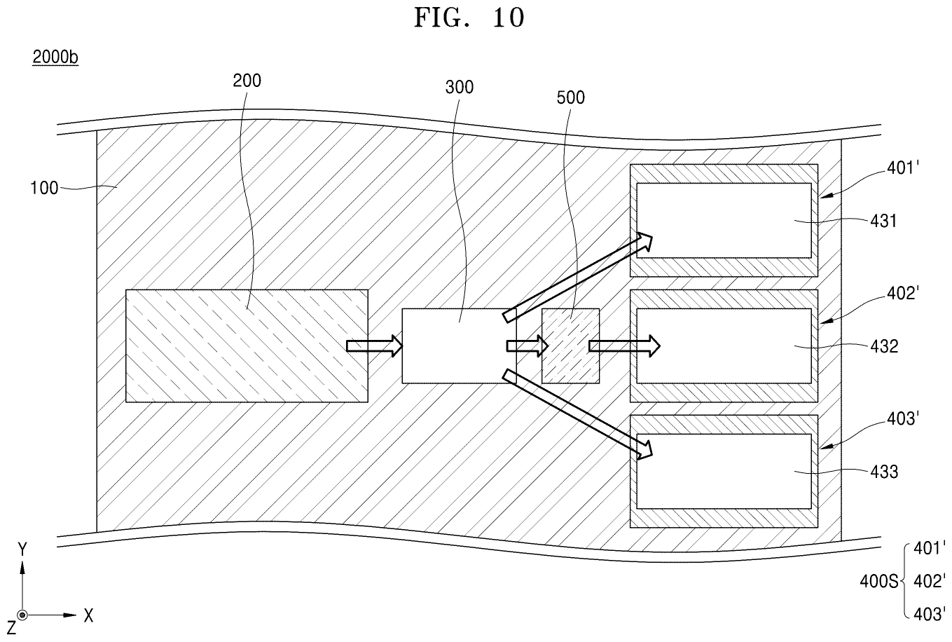

FIG. 10 is a plan view schematically illustrating a semiconductor package 2000b according to an embodiment.

Most of the components constituting the semiconductor package 2000b described below and the materials making up the components thereof are substantially the same as or similar to those described above with reference to FIG. 7. Therefore, for convenience of description, the differences between the semiconductor package 2000b of FIG. 10 and the semiconductor package 2000 of FIG. 7 are mainly described.

The semiconductor package 2000b may include the first package substrate 100, the power supply device 200, the power management semiconductor chip 300, the sub-battery 500, and a plurality of semiconductor devices 400S.

The semiconductor devices 400S may receive power from the power management semiconductor chip 300. For example, the power management semiconductor chip 300 may receive power from the power supply device 200 and output power in accordance with required power of the semiconductor devices 400S. For example, output power of the power supply device 200 may be equal to the sum of the required powers of the semiconductor devices 400S, and the power management semiconductor chip 300 may receive power from the power supply device 200 and distribute power to each of the semiconductor devices 400S according to the required power of each of the semiconductor device 400S.

In some embodiments, one of the semiconductor devices 400S may receive power from the sub-battery 500, and the others may receive power directly from the power management semiconductor chip 300. For example, the first package substrate 100 may include an internal interconnection connecting the power management semiconductor chip 300 to the sub-battery 500 and an internal interconnection connecting the sub-battery 500 to one of the semiconductor devices 400S. The first package substrate 100 may include an internal interconnection connecting the power management semiconductor chip 300 to each of the others of the semiconductor devices 400S.

In some embodiments, the semiconductor devices 400S may include a first semiconductor device 401′, a second semiconductor device 402′, and a third semiconductor device 403′. However, the number and location of the semiconductor devices 400S are not limited to those shown in FIG. 10.

Each of the first semiconductor device 401′, the second semiconductor device 402′, and the third semiconductor device 403′ may include a semiconductor chip. The first semiconductor device 401′ and the third semiconductor device 403′ may receive power from the power management semiconductor chip 300, and the second semiconductor device 402′ may receive power from the sub-battery 500.

For example, the power management semiconductor chip 300 may provide power to a first semiconductor chip 431 of the first semiconductor device 401′ and a third semiconductor chip 433 of the third semiconductor device 403′ and provide power to the sub-battery 500. The sub-battery 500 may provide power to a second semiconductor chip 432 of the second semiconductor device 402′. The second semiconductor chip 432 may receive power through the sub-battery 500, so the power stability of the semiconductor package 2000b may be improved.

While the present disclosure has been particularly shown and described with reference to embodiments thereof, it will be understood that various changes in form and details may be made therein without departing from the spirit and scope of the following claims.

What is claimed is:

1. A semiconductor package comprising:
a first package substrate;
a power supply device electrically connected to a top surface of the first package substrate;
a power management semiconductor chip electrically connected to the top surface of the first package substrate,
wherein the power management semiconductor chip is horizontally apart from the power supply device, and electrically connected to the power supply device through the first package substrate; and
a semiconductor device electrically connected to the top surface of the first package substrate,
wherein the semiconductor device is horizontally apart from the power management semiconductor chip, and electrically connected to the power management semiconductor chip through the first package substrate,
wherein the semiconductor device includes:
a second package substrate electrically connected to the top surface of the first package substrate;
a semiconductor chip electrically connected to a top surface of the second package substrate; and
a sub-battery electrically connected to the semiconductor chip through the second package substrate or directly connected to the semiconductor chip.

2. The semiconductor package of claim 1, wherein
the first package substrate is configured to transfer power output from the power supply device to the power management semiconductor chip through a first internal interconnection,
the first package substrate is further configured to transfer power output from the power management semiconductor chip to the second package substrate of the semiconductor device, through a second internal interconnection and
the second package substrate is configured to transfer power from the first package substrate to the sub-battery through a third internal interconnection.

3. The semiconductor package of claim 2, wherein
the second package substrate is further configured to transfer power output from the sub-battery to the semiconductor chip through a fourth internal interconnection, and
a rated voltage of the semiconductor chip is equal to an output voltage of the sub-battery.

4. The semiconductor package of claim 1, wherein
the power management semiconductor chip is one of a plurality of power management semiconductor chips, and
magnitudes of output voltages of the plurality of power management semiconductor chips are different from each other, and
the magnitudes of output voltages of the plurality of power management semiconductor chips correspond to one of a plurality of rated voltages of the semiconductor chip.

5. The semiconductor package of claim 4, wherein
a first power management semiconductor chip of the plurality of power management semiconductor chips supplies power to the sub-battery of the semiconductor device, and
one or more of remaining power management semiconductor chips of the plurality of power management semiconductor chips supplies power to the semiconductor chip of the semiconductor device.

6. The semiconductor package of claim 1, wherein the sub-battery is electrically connected to a lower surface of the second package substrate.

7. The semiconductor package of claim 1, wherein the sub-battery is surrounded on at least two sides by the second package substrate and wherein an upper surface of the sub-battery is on a same level as an upper surface of the second package substrate.

8. The semiconductor package of claim 1, wherein the sub-battery is electrically connected to an upper surface of the second package substrate and is apart from the semiconductor chip in a horizontal direction.

9. The semiconductor package of claim 1, wherein
the power supply device is configured to charge power, and
a volume of the power supply device is greater than a volume of the sub-battery.

10. The semiconductor package of claim 1, further comprising
the semiconductor device includes a first passive device electrically connected to the top surface of the first package substrate,
wherein the first package substrate is configured to transfer power output from the power management semiconductor chip to the semiconductor device through the first passive device.

11. The semiconductor package of claim 1, wherein
the semiconductor device further includes a second passive device,
wherein the second passive device is connected in parallel with the sub-battery.

12. A semiconductor package comprising:
a first package substrate;
a power supply device electrically connected to a top surface of the first package substrate;
a power management semiconductor chip electrically connected to the top surface of the first package substrate, wherein the power management semiconductor chip is horizontally apart from the power supply device, and electrically connected to the power supply device through the first package substrate;
a sub-battery electrically connected to the top surface of the first package substrate and configured to be charged by power output from the power management semiconductor chip; and
a semiconductor device electrically connected to the top surface of the first package substrate, wherein the semiconductor device comprises a second package substrate and a semiconductor chip electrically connected to a top surface of the second package substrate,
wherein the first package substrate is configured to transfer power from the sub-battery to the semiconductor device.

13. The semiconductor package of claim 12, wherein
the power management semiconductor chip is configured to lower a voltage of power supplied from the power supply device to a rated voltage of the sub-battery and output the power, and
the first package substrate is further configured to transfer power output from the power management semiconductor chip to the sub-battery and transfer power output from the sub-battery to the semiconductor device.

14. The semiconductor package of claim 12, wherein a distance between the sub-battery and the semiconductor device is less than a distance between the power management semiconductor chip and the semiconductor device.

15. The semiconductor package of claim 14, wherein the sub-battery is electrically connected to the top surface of the first package substrate between the semiconductor device and the power management semiconductor chip.

16. The semiconductor package of claim 12, wherein
the power management semiconductor chip is one of a plurality of power management semiconductor chips, and
output voltages of the plurality of power management semiconductor chips are different from each other.

17. The semiconductor package of claim 16, wherein
the first package substrate is further configured to transfer power from a first power management semiconductor chip among the plurality of power management semiconductor chips to the sub-battery, and
the first package substrate is further configured to transfer power from one or more of remaining power management semiconductor chips of the plurality of power management semiconductor chips to the semiconductor device.

18. The semiconductor package of claim 12, wherein
the semiconductor device is one of a plurality of semiconductor devices, and
the first package substrate is further configured to transfer power output from the sub-battery to one of the plurality of semiconductor devices and transfer power output from power management semiconductor chip to one or more of remaining semiconductor devices of the plurality of semiconductor devices and the sub-battery.

19. A semiconductor package comprising:
a first package substrate;
a power supply device electrically connected to a top surface of the first package substrate and configured to charge power;
a power management semiconductor chip electrically connected to the top surface of the first package substrate, wherein the power management semiconductor chip is horizontally apart from the power supply device, and electrically connected to the power supply device through the first package substrate; and
a semiconductor device electrically connected to the top surface of the first package substrate, wherein the semiconductor device is horizontally apart from the power management semiconductor chip, and electrically connected to the power management semiconductor chip through the first package substrate,
wherein the semiconductor device includes:
a second package substrate electrically connected to the top surface of the first package substrate;
a semiconductor chip electrically connected to a top surface of the second package substrate;
a sub-battery configured to supply power to the semiconductor chip; and
a molding layer electrically connected to the second package substrate and surrounding the semiconductor chip and the sub-battery,
wherein the first package substrate is configured to transfer power from the power management semiconductor chip to the second package substrate of the semiconductor device, and
the second package substrate is configured to transfer power received from the first package substrate to the sub-battery.

20. The semiconductor package of claim 19, wherein
a volume of the power supply device is greater than a volume of the sub-battery,
the sub-battery is located on an upper surface of the second package substrate,
an upper surface of the molding layer is coplanar with an upper surface of the sub-battery, and
the second package substrate is further configured to transfer power output from the sub-battery to the semiconductor chip.
